(19) United States
(12) Patent Application Publication
(10) Pub. No.: US 2013/0068970 A1
(43) Pub. Date: Mar. 21, 2013

(54) UV Irradiation Apparatus Having UV Lamp-Shared Multiple Process Stations

(71) Applicant: Kiyohiro Matsushita, Tokyo (JP)

(72) Inventor: Kiyohiro Matsushita, Tokyo (JP)

(73) Assignee: ASM JAPAN K.K., Tokyo (JP)

(21) Appl. No.: 13/238,960

(22) Filed: Sep. 21, 2011

(51) Int. Cl. H01L 21/26; B01J 19/12

(52) U.S. Cl. 250/492.2; 250/492.1

(57) ABSTRACT

A UV irradiation apparatus for treating substrates includes: at least two process stations each provided with a UV transmissive window; at least one electric UV lamp using two electrodes in a gas tube extending over the UV transmissive windows of the process stations aligned along the gas tube and shared by the process stations; a UV transmissive zone disposed between the UV lamp and the process stations and provided with reflectors; and shutters for blocking UV light from being transmitted to the respective process stations independently.

### BACKGROUND OF THE INVENTION

1. Field of the Invention

The present invention generally relates to a UV irradiation apparatus for treating substrates, particularly to such a UV irradiation apparatus having multiple reaction stations.

2. Description of the Related Art

In recent years, UV curing is performed in order to increase strength of low-k films or forming pores in low-k films. Conventionally, each UV process region is equipped with one or more UV lamps as shown in U.S. Patent Publication No. 2006/251827. One UV lamp is provided with one power supply and one control unit, and thus, when increasing the number of UV process regions in order to increase throughput, the number of power supplies and control units will be the product of the number of UV process regions and the number of UV lamps, thereby increasing the total cost and footprint of the apparatus. Considering the above, one object of the present invention, among others, is to achieve simplification and downsizing of the apparatus structures. Conventionally, electrodeless UV lamps are used. However, based on contemporarily available technology, it is difficult to increase the length and/or illuminance power of electrodeless UV lamps.

Any discussion of problems and solutions involved in the related art has been included in this disclosure solely for the purposes of providing a context for the present invention, and should not be taken as an admission that any or all of the discussion were known at the time the invention was made.

### SUMMARY OF THE INVENTION

According to an embodiment, a UV irradiation apparatus for treating substrates comprises: (i) at least two process stations disposed closely to each other, each process station being adapted to process a substrate placed therein and being provided with a UV transmissive window for transmitting UV light therethrough; and (ii) at least one electric UV lamp disposed above the UV transmissive windows of the process stations and shared by the process stations for processing the substrates placed in the respective process stations by UV light transmitted from the UV lamp through the respective UV transmissive windows, said electric UV lamp using two electrodes in a gas tube which is aligned and has a length to extend over the UV transmissive windows of the at least two process stations. In some embodiments, the UV irradiation apparatus further comprises (iii) a UV transmissive zone disposed between the UV lamp and the process stations and provided with reflectors for directing UV light emitted from the UV lamp to the transmissive windows, wherein substantially all UV light emitted from its front side facing the UV transmissive zone is emitted to the transmissive zone. In some embodiments, the UV irradiation apparatus further comprises (iv) shutters for blocking UV light emitted from the UV lamp from being transmitted to the respective process stations through the respective transmissive windows, each shutter being disposed between each transmissive window and the UV lamp and being operable independently of each other.

According to another embodiments, a UV irradiation apparatus for treating semiconductor substrates comprises: at least two process stations each provided with a UV transmissive window; at least one electric UV lamp using two electrodes in a gas tube which is aligned and has a length to extend over the UV transmissive windows of the at least two process stations so that the lamp is shared by the process stations; a UV transmissive zone disposed between the UV lamp and the process stations and provided with reflectors; and shutters for blocking UV light from being transmitted to the respective process stations independently.

Since one gas tube of the UV lamp is aligned and has a length effective to irradiate multiple substrates placed in the respective process stations, substantially uniform and highly efficient irradiation can be conducted on the multiple process stations, and also, the number of gas tubes, illuminometers, power supply devices, and control units necessary for operating UV irradiation can effectively be reduced, thereby simplifying the system as a whole. In some embodiments, by disposing a UV transmissive zone with reflectors between the UV lamp and the multiple process stations, substantially all UV light emitted from its front side facing the UV transmissive zone can be emitted to the transmissive zone. In some embodiments, by disposing a shutter between each transmissive window and the UV lamp, the multiple process stations can be operable independently of each other.

The present invention may equally be applied to UV apparatuses and methods of treating a substrate using the UV apparatuses.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1 illustrates a schematic side view (FIG. 1(a)) and a schematic top view (FIG. 1(b)) of an apparatus combining a UV unit and process stations, desirably in conjunction with controls programmed to conduct the sequences described below, which can be used in an embodiment of the present invention.

FIG. 2 illustrates a schematic side view (FIG. 2(a)) and a schematic top view (FIG. 2(b)) of an apparatus combining a UV unit and process stations, desirably in conjunction with controls programmed to conduct the sequences described below, which can be used in another embodiment of the present invention.

FIG. 3 illustrates a schematic side view (FIG. 3(a)) and a schematic top view (FIG. 3(b)) of an apparatus combining a UV unit and process stations, desirably in conjunction with controls programmed to conduct the sequences described below, which can be used in still another embodiment of the present invention.

FIG. 4 illustrates a schematic top view of a UV apparatus having four process stations according to an embodiment of the present invention.

FIGS. 5A and 5B are schematic perspective views of a shutter according to an embodiment of the present invention. FIG. 5A illustrates a closed state, whereas FIG. 5b illustrates an open state.

FIG. 6 illustrates a partial schematic side view of a UV apparatus having an illuminometer according to an embodiment of the present invention.

FIG. 7 illustrates a schematic view of a UV unit with an air cooling system according to an embodiment of the present invention.

FIG. 8 illustrates a schematic view of a UV unit with a heat exchanging cooling system according to an embodiment of the present invention.

### DETAILED DESCRIPTION OF EMBODIMENTS

In this disclosure, “a gas” may include vaporized solid and/or liquid and may be constituted by a mixture of gases. Likewise, “a” refers to a species or a genus including multiple species. Further, in this disclosure, any two numbers of a variable can constitute an applicable range of the variable, and any ranges indicated may include or exclude the endpoints. In this disclosure, “multiple process stations” or “multiple stations” refers to two or more stations/sections disposed closely to each other and viewed substantially as, e.g. physically, functionally, and/or cognitively, separated or isolated from each other, which include, but are not limited to, multiple chambers which are physically, structurally, and operationally separated from each other (e.g., dual chambers wherein two separate chambers are connected to each other), and multiple regions which are cognitively and positionally isolated from each other (e.g., dual regions wherein two isolated regions are disposed in one chamber). In some embodiments, the multiple process stations are continuously aligned, wherein “continuously” refers to without being exposed to an ambient atmosphere or physically connected.

In the present disclosure where conditions and/or structures are not specified, the skilled artisan in the art can readily provide such conditions and/or structures, in view of the present disclosure, as a matter of routine experimentation. Also, in the present disclosure including the examples described later, the numbers applied in specific embodiments can be modified by a range of at least ±50% in some embodiments, and the ranges applied in some embodiments may include or exclude the lower and/or upper endpoints. Further, the numbers include approximate numbers, and may refer to average, median, representative, majority, etc. in some embodiments. In all of the disclosed embodiments, any element used in an embodiment can interchangeably or additionally be used in another embodiment unless such a replacement is not feasible or causes adverse effect or does not work for its intended purposes. Further, the present invention can equally be applied to apparatuses and methods.

In the disclosure, “substantially all”, “substantially uniform”, or the like may refer to an immaterial difference or a difference recognized by a skilled artisan such as those of less than 10%, less than 5%, less than 1%, or any ranges thereof in some embodiments. Also, in the disclosure, “substantially different”, “substantially less” or the like may refer to a material difference or a difference recognized by a skilled artisan such as those of at least 1%, 5%, 10%, 20%, 30%, 40%, 50%, 60%, 70%, 80%, or any ranges thereof in some embodiments.

In this disclosure, any defined meanings do not necessarily exclude ordinary and customary meanings in some embodiments.

As described above, some embodiments provide a UV irradiation apparatus for treating substrates, comprising: (i) at least two process stations disposed closely to each other, each process station being adapted to process a substrate placed therein and being provided with a UV transmissive window for transmitting UV light therethrough; and (ii) at least one electric UV lamp disposed above the UV transmissive windows of the process stations and shared by the process stations for processing the substrates placed in the respective process stations by UV light transmitted from the UV lamp through the respective UV transmissive windows, said electric UV lamp using two electrodes in a gas tube which is aligned and has a length to extend over the UV transmissive windows of the at least two process stations; and optionally, but typically, (iii) a UV transmissive zone disposed between the UV lamp and the process stations and provided with reflectors for directing UV light emitted from the UV lamp to the transmissive windows, wherein substantially all UV light emitted from its front side facing the UV transmissive zone is emitted to the transmissive zone; and/or (iv) shutters for blocking UV light emitted from the UV lamp from being transmitted to the respective process stations through the respective transmissive windows, each shutter being disposed between each transmissive window and the UV lamp and being operable independently of each other.

In some embodiments, the transmissive zone is divided into at least two sub-zones corresponding to the at least two process stations, and the reflectors include a partition reflector dividing the two sub-zones, said partition reflector having a shape having an up-pointing cross section such that the partition reflector reflects UV light from the UV lamp toward the transmissive windows. Since substantially all UV light emitted from its front side facing the UV transmissive zone is emitted to the transmissive zone, the shape of the partition reflector is typically an up-pointing shape. In some embodiments, the shape of the up-pointing cross section is substantially a triangle, e.g., an up-pointing acute-angled triangle. The height of the partition reflector may be substantially the same as that of the UV transmissive zone, or may be substantially shorter than that of the UV transmissive zone (by e.g., 20% to 40%), or no partition reflector is provided. When the height of the partition reflector is substantially the same as that of the UV transmissive zone, each sub-zone is isolated from another sub-zone by the partition reflector. In some embodiments, the partition reflector has an embankment-like shape disposed between the sub-zones. Preferably, the partition reflector is used so that light can be more efficiently directed to the transmissive windows.

In some embodiments, the shutters are interposed between the UV lamp and the top of the UV transmissive zone. In some embodiments, the shutters are disposed at the bottom of the UV transmissive zone immediately above the transmissive windows. When the partition reflector defines and isolates the sub-zones, the shutters can be located either on the top or at the bottom of the UV transmissive zone. When the sub-zones are not defined, the shutters are disposed at the bottom of the UV transmissive zone.

In some embodiments, the gas tube is a straight tube. The UV lamp is not an electrodeless lamp. A single electrodeless lamp is not extendable over multiple transmissive windows and its luminance power cannot be significantly increased due to its mechanism and contemporary technology. The gas tube of the UV lamp has typically two electrodes at the ends, and the gas tube can be extended as much as is necessary, and the luminance power can be increased. The gas tube can be a straight tube, but can also be a ring-shaped tube. The lamp can be any UV-light emitting lamp such as a mercury lamp or halogen lamp. In some embodiments, the UV lamp generates light covering a wide wavelength range from DUV to infrared, and mercury lamps are particularly suited for this application. Mercury lamps are classified by the internal lamp pressure into various types from low-pressure to ultrahigh-pressure types associated with wavelengths of 185 nm, 254 nm, 365 nm, etc., and any type can be selected as deemed appropriate (light with a wavelength shorter than 300 nm is effective in curing low-k films). Mercury lamps break the —CH₃ bond or —Si—O bond in a low-k film and then allow the broken components to re-bond to build an O—Si—O network to enhance the mechanical strength of the film. In some embodiments, the gas tube is a straight tube having a length greater than the diameter of the transmissive window. The gas tube extends over multiple transmissive windows, and thus, typically its length is greater than the diameter of the transmissive window. In the above, light emitted from the gas tube can be converged to the transmissive window using reflectors, thereby providing sufficient luminance to the transmissive window. In some embodiments, the length of the gas tube is in a range of about 200 cm to about 1,000 cm, typically about 400 cm to about 600 cm as measured as a straight tube. In some embodiments, the UV lamp has a power of about 4,000 W to about 20,000 W, typically about 800 W to about 1,200 W.

In some embodiments, the gas tube is a straight tube having a length greater than the diameter of the transmissive window multiplied by the number of the process stations continuously aligned along the gas tube. In some embodiments, multiple gas tubes (e.g., 2, 3, or 4 gas tubes) are disposed in parallel to each other, each extending over the transmissive windows aligned along the gas tubes, wherein the length of the gas tubes may be different or the same (e.g., the tube(s) closer to the center is/are longer).

In some embodiments, each process station is constituted by a chamber physically isolated from another. For example, two process stations are constituted by two physically isolated chambers which have physically separate interiors, e.g., chambers disclosed in co-assigned U.S. patent application Ser. No. 13/154,271, the disclosure of which is herein incorporated by reference in its entirety. In some embodiments, the at least two process stations are constituted by a chamber having an interior shared by the at least two process stations, e.g., chambers disclosed in U.S. Pat. No. 5,855,681, the disclosure of which is herein incorporated by reference in its entirety. In some embodiments, more than two process stations constitute an apparatus. For example, three process stations are aligned in a line, or four process stations are arranged two-by-two, e.g., chambers disclosed in U.S. Patent Publication No. 2006/0251827, No. 2010/317198, No. 2010/089320, and No. 2008/241384, each disclosure of which is herein incorporated by reference in its entirety. In some embodiments, any of the transmissive zones disclosed herein can be attached to any of the foregoing chambers.

In some embodiments, each process station is provided with gas nozzles disposed along the outer periphery of the transmissive window, each gas nozzle being arranged to dispense a gas in a direction toward the center of the transmissive window. For example, gas nozzles can be installed in a circular flange attached to a chamber for supporting a transmissive window, wherein the flange is provided with a circular gas flow channel therein having multiple nozzles (e.g., 4 to 18 nozzles) extending from the channel toward the center for dispensing gas in a direction toward the center along the surface of the transmissive window. In some embodiments, a single gas nozzle can be used. The process station is also provided with an exhaust port, from which gas is discharged from the process station.

In some embodiments, the at least two process stations aligned along the gas tube are provided with a single shared illuminometer. Since the UV lamp is shared by the process stations, a single illuminometer can effectively monitor luminance emitted from the UV lamp, thereby reducing the number of illuminometers necessary for operation of the apparatus. In some embodiments, each sub-zone can be provided with an illuminometer. The illuminometer can be installed through the reflector and directed toward the UV lamp.

In some embodiments, the gas tube is provided with a cooling jacket which is connected to an external cooling device. Since the UV lamp is shared by the process stations, one cooling system per UV lamp can also be shared by the process stations, thereby reducing the number of cooling systems necessary for operation of the apparatus. In some embodiments, the cooling jacket encloses the gas tube and is connected to an air blower or a heat exchanger so that temperature-controlled air or cooling medium flows along the outer surface of the gas tube, thereby cooling the gas tube. In some embodiments, any suitable cooling systems can be used, such as that disclosed in U.S. Pat. No. 7,763,869, the disclosure of which is herein incorporated by reference in its entirety.

In some embodiments, each process station is adapted to process a 300-mm semiconductor wafer. In some embodiments, each process station is adapted to process a 200-mm semiconductor wafer. In some embodiments, the UV lamp has power effective to anneal multiple 300-mm/200-mm semiconductor wafers.

In some embodiments, the disclosed apparatuses may include one or more of the following embodiments:

1) Each process station is provided with a heater table on which a substrate is placed, a UV transmissive window disposed above the heater table, and gas nozzles for substantially uniformly supplying purge gas and/or process gas therein.

2) Each transmissive window is provided with an individual shutter so that illumination time can individually be controlled by individually and independently opening and closing each shutter for each process station.

3) One or more optical filters can be installed between the transmissive window and the shutter so that wavelengths of light can individually be adjusted depending on the process station.

4) A single UV unit is mounted on all of the transmissive windows of the process stations.

5) The optimal length and optimal number of UV lamps installed inside the UV unit are selected so as to substantially uniformly emit light to all of the transmissive windows at sufficient illuminance.

6) A reflector or reflectors are disposed under each UV lamp per transmissive window, thereby efficiently and substantially uniformly converging light to the transmissive window.

7) The UV lamp can be any suitable UV light-emitting lamp including a mercury lamp and halogen lamp.

8) The UV lamp has two electrodes and has a length sufficient to emit light simultaneously to multiple process stations.

By integrating or combining UV units, it is possible to reduce the number of illuminometers and/or cooling systems such as blowers and/or chiller by substantially half. Since the cost of lamps including their power supplies accounts for approximately 60% of the cost of a UV unit, by using a lamp having increased illuminance intensity and increased length so as to increase an irradiation area per lamp, it is possible to process more process stations without increasing the installation cost. The above cannot be achieved by using electrodeless lamps since sufficiently high power electrodeless lamps are not known in the art, and thus, in order to increase overall illuminance intensity, it is necessary to increase the number of lamps and/or UV units. In some embodiments, no electrodeless lamp is used in the apparatus.

The embodiments will be explained with respect to preferred embodiments. However, the present invention is not limited to the preferred embodiments. A skilled artisan will appreciate that the apparatus includes one or more controller(s) (not shown) programmed or otherwise configured to cause the UV treatment (and reactor cleaning processes) described elsewhere herein to be conducted. The controller(s) are communicated with the various power sources, heating systems, pumps, robotics and gas flow controllers or valves of the reactor, as will be appreciated by the skilled artisan.

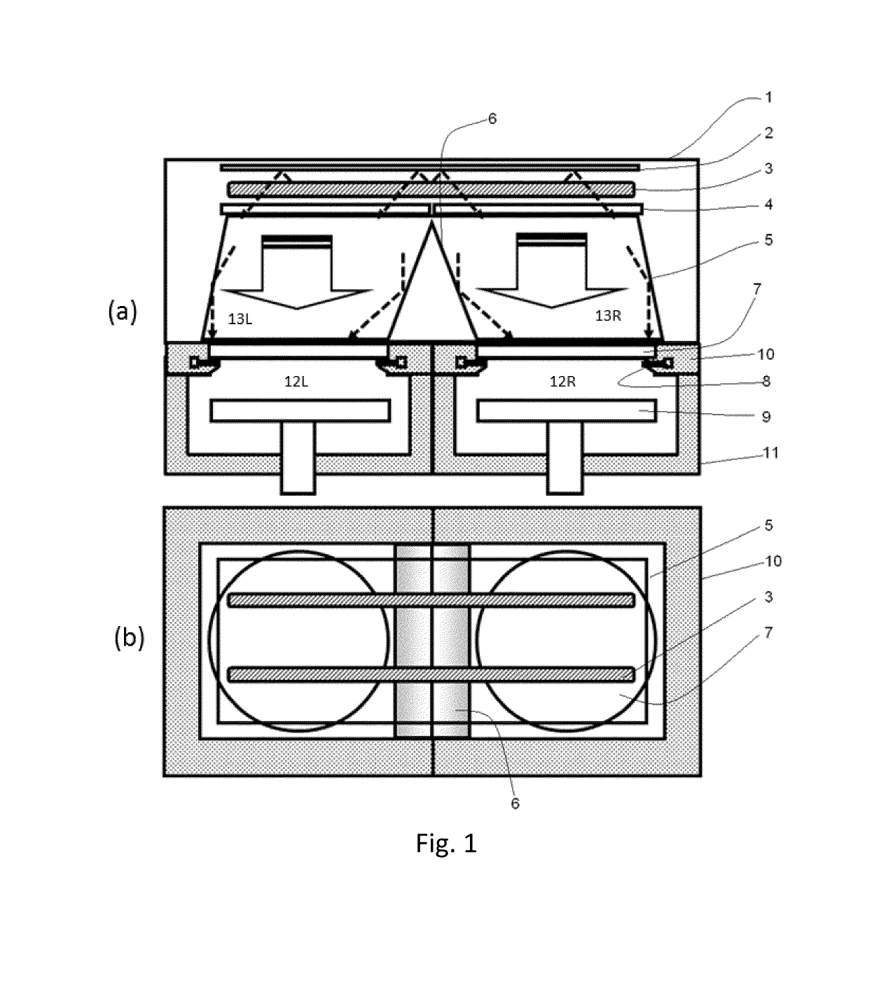

FIG. 1 illustrates a schematic side view (FIG. 1(a)) and a schematic top view (FIG. 1(b)) of an apparatus combining a UV unit and process stations, desirably in conjunction with controls programmed to conduct the sequences described below, which can be used in an embodiment of the present invention.

A UV unit 1 is mounted on process stations 11. In this embodiment, the process stations 11 are composed of two discrete chambers having two physically discrete interiors 12L, 12R. The two chambers are connected to each other via their side walls. Each chamber 11 includes a heater table 9 and has a flange 10 on its top which includes a UV transmissive window 7 and gas nozzles 8 disposed along the outer periphery of the transmissive window 7. The transmissive window 7 is used to irradiate uniform UV light, and made of synthetic quartz, for example. This window can be made of any material, as long as it can shield the interior of the chamber 11 from atmosphere but allow UV light to transmit through. The UV light source 3 (UV lamp) in the UV unit 1 has multiple gas tubes (in this case, two gas tubes) that are arranged in parallel with one another. As shown in FIG. 1(b), this light source is properly arranged to achieve uniform intensity, and a reflector 2 disposed behind the lamp 2, a reflector 5 disposed between the lamp 2 and the transmissive window 7 around the outer periphery of the transmissive windows except for the boundary between the transmissive windows, and a reflector 6 disposed between the transmissive windows 7 are provided to allow UV light from each UV tube to be reflected toward the transmissive window 7. The reflectors 5, 6 define sub-zones 13L, 13R for transmitting UV light emitted from the lamp to the respective interiors 12L, 12R through the respective transmissive windows 7. The reflector 6 has an embankment having an up-pointing triangular cross section as illustrated so as to effectively reflect UV light toward the transmissive window. Due to the reflectors 2, 5, 6, despite the fact that the gas tube extends over the two transmissive windows, substantially all UV light can be transmitted to the transmissive windows. The tube 3 is made of glass, such as synthetic quartz, that allows UV light to transmit through. In this embodiment, the UV lamp 3 is structured in such a way that it can easily be removed and replaced. In the figure, the broken lines with arrows represent reflection of light, and thick arrows represent irradiation of light.

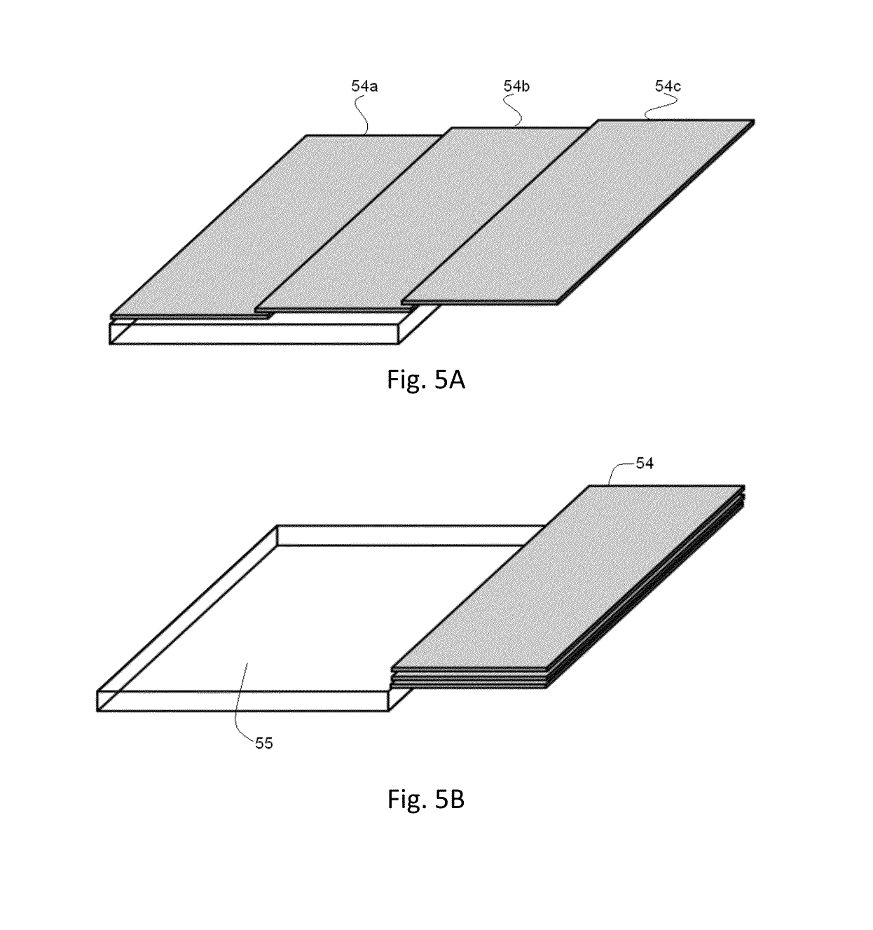

Shutters 4 are provided between the UV lamp 2 and the sub-zones 13L, 13R in a way such that the shutters are closed and opened independently of each other so that the sub-zones 13L, 13R can individually and independently be controlled. FIGS. 5A and 5B illustrate a structure of the shutter according to some embodiments. The shutter is constituted by extendable plates 54. The plates 54 are comprised of plates 54a, 54b, 54c wherein the plates 54a, 54b are extendable by sliding to close the top 55 of the sub-zone as illustrated in FIG. 5A. The plates 54a, 54b are retractable by sliding and placed under the plate 54c to open the top 55 of the sub-zone as illustrated in FIG. 5B. The shutter may be made of aluminum or stainless steel, for example.

In this apparatus, the substrate process station that can be controlled at various conditions between vacuum and near atmosphere is separated from the UV unit 1 by the flange 10 in which the transmissive window 7 is set. The sub-zones may be filled with nitrogen, for example. Also in this embodiment, gas is introduced through the flange 10, where multiple gas nozzles 8 are provided and arranged symmetrically to create a substantially uniform processing atmosphere. In the UV irradiation process, the chamber 11 may be filled with gas selected from Ar, CO, CO₂, C₂H₄, CH₄, H₂, He, Kr, Ne, N₂, O₂, Xe, alcohol gases, and/or organic gases, and its pressure may be adjusted to a range of approx. 0.1 Torr to near atmosphere (including 1 Torr, 10 Torr, 50 Torr, 100 Torr, 1,000 Torr, and values between any two numbers of the foregoing), and then a processing target, or semiconductor substrate carried in through a substrate transfer port via a gate valve (not shown), is placed on the heater table 9 whose temperature may be set to a range of approx. 0° C. to approx. 650° C. (including 10° C., 50° C., 100° C., 200° C., 300° C., 400° C., 500° C., 600° C., and values between any two numbers of the foregoing, but preferably in a range of 300° C. to 450° C.), after which UV light with a wavelength in a range of approx. 100 nm to approx. 400 nm (including 150 nm, 200 nm, 250 nm, 300 nm, 350 nm, and values between any two numbers of the foregoing, but preferably in a range of approx. 200 to 250 nm) may be irradiated at an output in a range of approx. 1 mW/cm² (per area of the substrate) to approx. 1,000 mW/cm² (including 10 mW/cm², 50 mW/cm², 100 mW/cm², 200 mW/cm², 500 mW/cm², 800 mW/cm², and values between any two numbers of the foregoing) onto a film on the substrate by keeping an appropriate distance from the UV light source (the height of the sub-zone may be approx. 5 to 40 cm, whereas the distance between the transmissive window 7 and the substrate may be approx. 0.5 to 10 cm). Use of UV light with a wavelength of preferably 300 nm or shorter, or more preferably 250 nm or shorter, will maximize the effect of UV irradiation (such as curing of low-k film) while suppressing heat generation. The irradiation time may be in a range of approx. 1 sec to approx. 60 min (including 5 sec, 10 sec, 20 sec, 50 sec, 100 sec, 200 sec, 500 sec, 1,000 sec, and values between any two numbers of the foregoing). The chamber is evacuated via an exhaust port (not shown). This semiconductor manufacturing apparatus performs a series of processing steps according to an automatic sequence, where the specific processing steps include gas introduction, UV irradiation, stopping of irradiation, and stopping of gas supply.

The apparatus can be operated as follows: A substrate is placed on each heater table 9 which is heated to a set temperature. The interiors 12L, 12R of the chambers 11 are filled with a gas supplied from the gas nozzles 8 at a set pressure. The sub-zones 13L, 13R are filled with a gas, and the UV lamp 3 is activated. The shutters open so that UV light emitted from the UV lamp 2 is emitted to the interiors 12L, 12R through the windows 7, thereby irradiating the substrates with UV light.

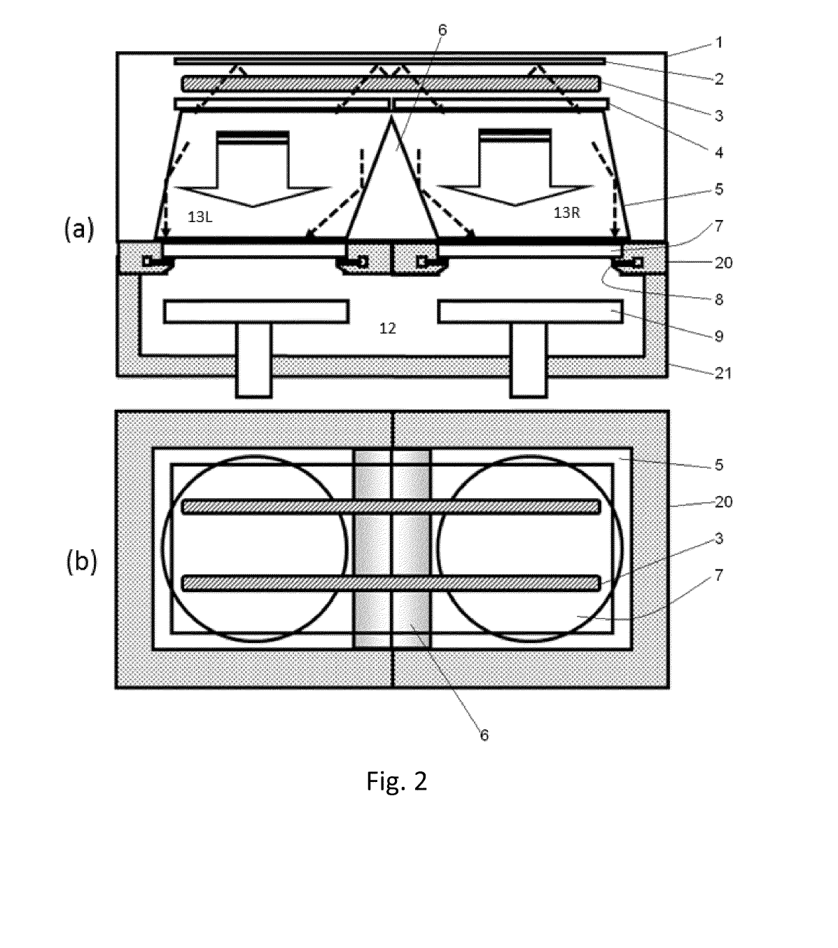

FIG. 2 illustrate a schematic side view (FIG. 2(a)) and a schematic top view (FIG. 2(b)) of an apparatus combining a UV unit and process stations, desirably in conjunction with controls programmed to conduct the sequences described below, which can be used in another embodiment of the present invention. The differences between the apparatus illustrated in FIG. 1 and that illustrated in FIG. 2 are that in the apparatus of FIG. 2, the process stations (each process station is defined as a station equipped with an individual transmissive window) share the interior 12 and are constituted by a single chamber 21, on which a flange 20 is placed. Although the interior is shared by the process stations, each station is equipped with the individual transmissive window 7 and the individual gas nozzles 8.

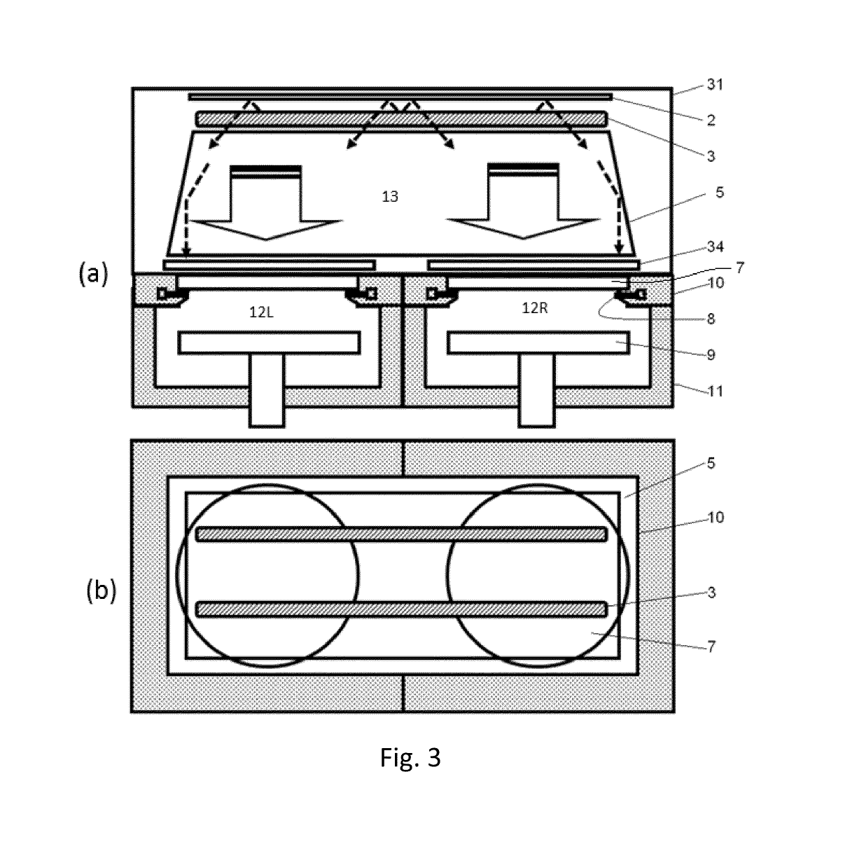

FIG. 3 illustrate a schematic side view (FIG. 3(a)) and a schematic top view (FIG. 3(b)) of an apparatus combining a UV unit and process stations, desirably in conjunction with controls programmed to conduct the sequences described below, which can be used in still another embodiment of the present invention. The differences between the apparatus illustrated in FIG. 1 and that illustrated in FIG. 3 are that in the apparatus of FIG. 3, no partition reflector is used, and there is a shared transmissive zone 13, and shutters 34 are disposed at the bottom of the zone 13 immediately above the transmissive windows 7. Substantially all UV light emitted from the UV lamp 3 can be transmitted to the transmissive zone 13, but because no partition reflector is used, part of the UV light emitted from the UV lamp may not pass through the transmissive windows 7.

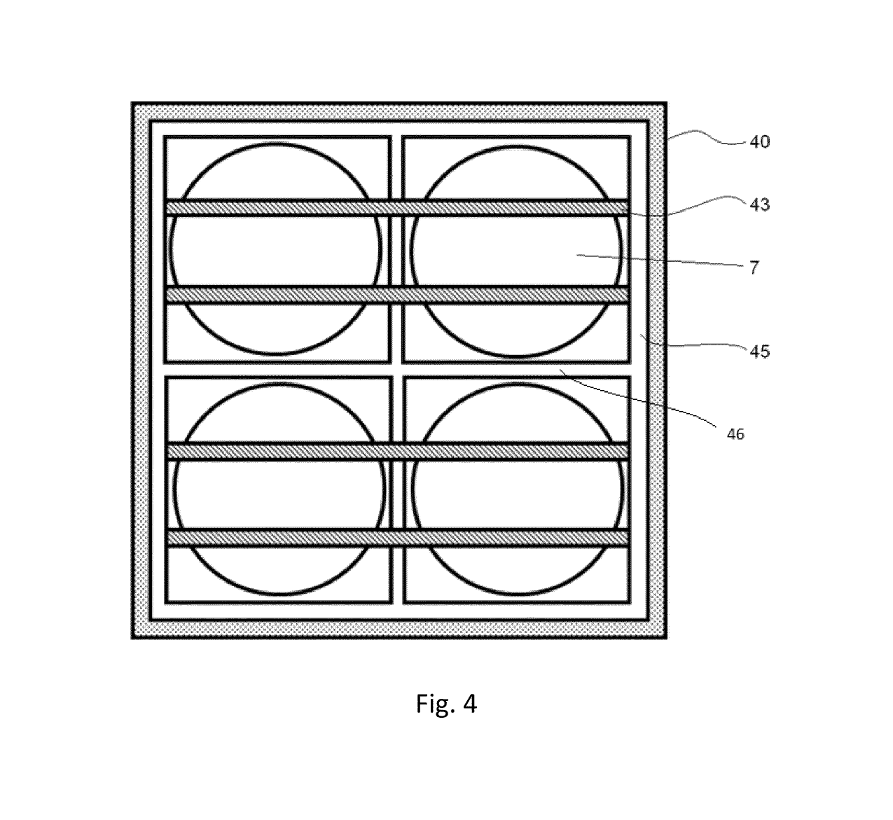

FIG. 4 illustrates a schematic top view of a UV apparatus having four process stations according to an embodiment of the present invention. In this embodiment, two UV lamps 43 are arranged in parallel to each other and extend over two transmissive windows 7. On top of a flange 40, the UV unit is mounted. A reflector 45 encloses the four transmissive windows, and a partition reflector 46 is provided between two adjacent transmissive windows. In some embodiments, a ring-shaped gas tube can be installed so that it can cover all four transmissive windows.

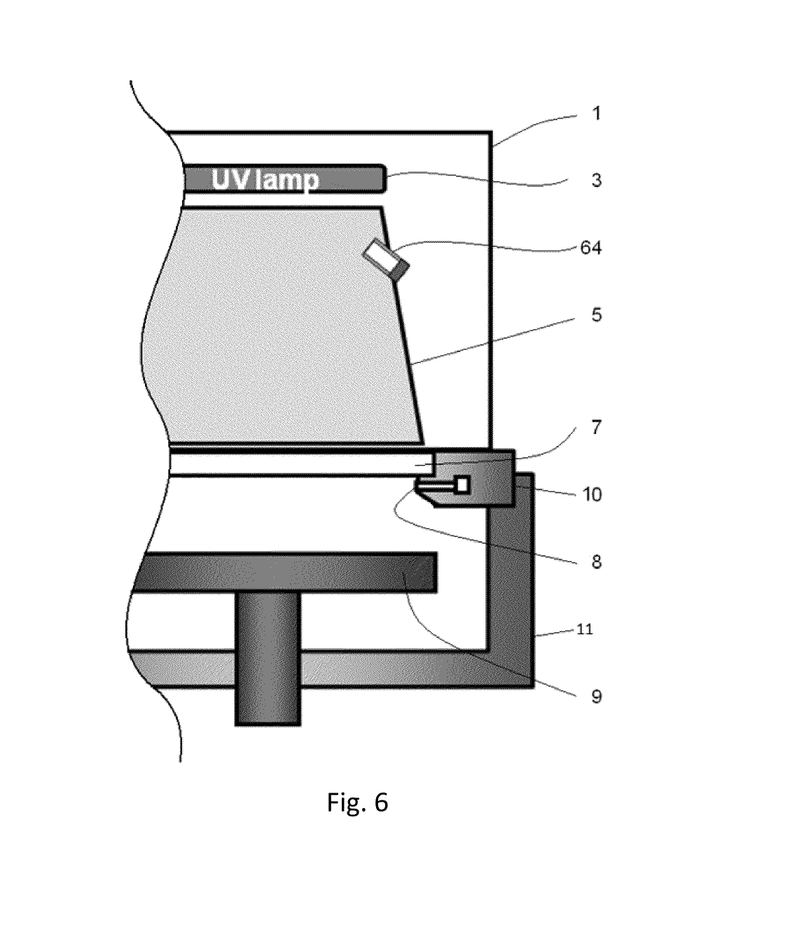

FIG. 6 illustrates a partial schematic side view of a UV apparatus having an illuminometer according to an embodiment of the present invention. A UV illuminometer 64 is installed in the transmissive zone through an upper portion of the reflector 5 and is directed to the UV lamp 3 to measure the intensity of UV light irradiated from the UV lamp 3. The illuminometer 64 sends signals to an intensity monitor to control the power to the UV lamp 3. The illuminometer can be installed inside the interior of the process station, or above the shutter. When the illuminometer is installed above the shutter, it can be shared by the process stations aligned along the UV lamp.

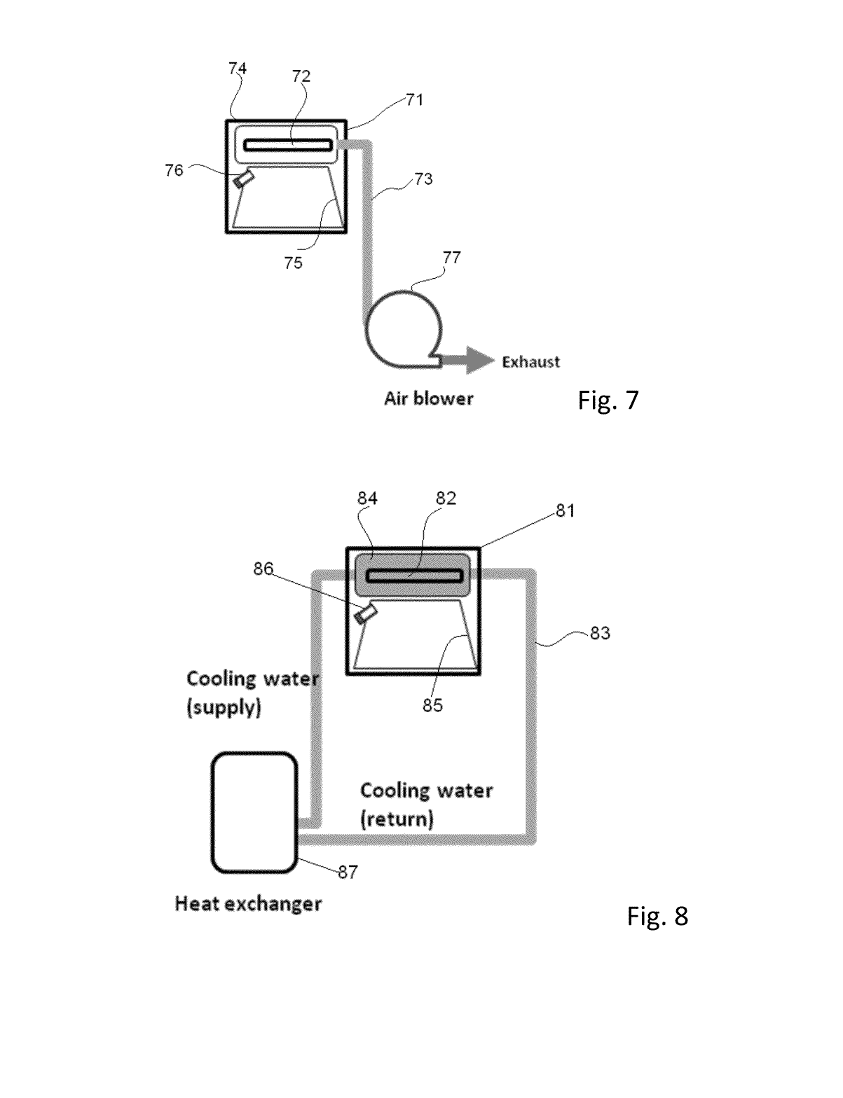

FIG. 7 illustrates a schematic view of a UV unit with an air cooling system according to an embodiment of the present invention. The process stations are omitted from the figure. A UV unit 71 includes a UV lamp 72 enclosed by a cooling jacket 74 which is connected to an air blower 77 via a cooling pipe 73. The air blower 77 blows out air from a space defined between the UV lamp 72 and the cooling jacket 74 through the cooling pipe 73, thereby removing heated air from the space defined between the UV lamp 72 and the cooling jacket 74 and cooling the UV lamp 72. Air can flow into the space through an air inflow port (not shown). The UV unit 71 also includes a reflector 75 with an illuminometer 76.

FIG. 8 illustrates a schematic view of a UV unit with a heat exchanging cooling system according to an embodiment of the present invention. The process stations are omitted from the figure. A UV unit 81 includes a UV lamp 82 enclosed by a cooling jacket 84 which is connected to a heat exchanger 87 via a cooling pipe 83. The heat exchanger 87 circulates a coolant such as water through the cooling pipe 83 and the cooling jacket 84. The coolant flows along the UV lamp, thereby cooling the UV lamp 82. The UV unit 81 also includes a reflector 85 with an illuminometer 86.

As shown in FIGS. 7 and 8, since the cooling system is provided for the UV lamp and is also shared by the process stations, the number of air blowers/heat exchangers installed for multiple process stations can significantly be reduced. Likewise, the power supply for the lamp can also be shared by the process stations, thereby reducing the number of the power supplies installed for multiple process stations.

For example, according to an embodiment of the present invention (where two process stations share three UV lamps), the cost can be reduced by 40% as compared with a conventional UV apparatus (where each of two process stations uses three UV lamps) as shown below. The total cost of the conventional UV apparatus will be $252,500 (lamp: $6,250×6; power unit: $8,750×6; UV unit: $50,000×2; chiller unit: $18,750×2), whereas the total cost of the embodiment will be $151,250 (lamp: $8,750×3; power unit: $12,500×3; UV unit: $62,500×1; chiller unit: $25,000×1).

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A UV irradiation apparatus for treating substrates, comprising:
at least two process stations disposed closely to each other, each process station being adapted to process a substrate placed therein and being provided with a UV transmissive window for transmitting UV light therethrough; and
at least one electric UV lamp disposed above the UV transmissive windows of the process stations and shared by the process stations for processing the substrates placed in the respective process stations by UV light transmitted from the UV lamp through the respective UV transmissive windows, said electric UV lamp using two electrodes in a gas tube which is aligned and has a length to extend over the UV transmissive windows of the at least two process stations.

2. The UV irradiation apparatus according to claim 1, further comprising:
a UV transmissive zone disposed between the UV lamp and the process stations and provided with reflectors for directing UV light emitted from the UV lamp to the transmissive windows, wherein substantially all UV light emitted from its front side facing the UV transmissive zone is emitted to the transmissive zone.

3. The UV irradiation apparatus according to claim 1, further comprising:
shutters for blocking UV light emitted from the UV lamp from being transmitted to the respective process stations through the respective transmissive windows, each shutter being disposed between each transmissive window and the UV lamp and being operable independently of each other.

4. The UV irradiation apparatus according to claim 2, wherein the transmissive zone is divided into at least two sub-zones corresponding to the at least two process stations, and the reflectors include a partition reflector dividing the two sub-zones, said partition reflector having a shape having an up-pointing triangular cross section such that the partition reflector reflects UV light from the UV lamp toward the transmissive windows.

5. The UV irradiation apparatus according to claim 4, wherein the shutters are interposed between the UV lamp and the UV transmissive zone.

6. The UV irradiation apparatus according to claim 1, wherein the gas tube is a straight tube having a length greater than the diameter of the transmissive window.

7. The UV irradiation apparatus according to claim 1, wherein the gas tube is a straight tube having a length greater than the diameter of the transmissive window multiplied by the number of the process stations continuously aligned along the gas tube.

8. The UV irradiation apparatus according to claim 1, wherein each process station is constituted by a chamber physically isolated from another.

9. The UV irradiation apparatus according to claim 1, wherein the at least two process stations are constituted by a chamber having an interior shared by the at least two process stations.

10. The UV irradiation apparatus according to claim 1, wherein each process station is provided with gas nozzles disposed along the outer periphery of the transmissive window, each gas nozzle being arranged to dispense a gas in a direction toward the center of the transmissive window.

11. The UV irradiation apparatus according to claim 1, wherein the at least two process stations aligned along the gas tube are provided with a single shared illuminometer.

12. The UV irradiation apparatus according to claim 1, wherein the gas tube is provided with a cooling jacket which is connected to an external cooling device.

13. The UV irradiation apparatus according to claim 1, wherein each process station is adapted to process a 300-mm semiconductor wafer.

14. The UV irradiation apparatus according to claim 13, wherein the UV lamp has power effective to anneal multiple 300-mm semiconductor wafers.

15. A UV irradiation apparatus for treating semiconductor substrates comprising: at least two process stations each provided with a UV transmissive window; at least one electric UV lamp using two electrodes in a gas tube which is aligned and has a length to extend over the UV transmissive windows of the at least two process stations so that the lamp is shared by the process stations; a UV transmissive zone disposed between the UV lamp and the process stations and provided with reflectors; and shutters for blocking UV light from being transmitted to the respective process stations independently.
